(19) United States
(12) Patent Application Publication
(10) Pub. No.: US 2001/0054762 A1
(43) Pub. Date: Dec. 27, 2001

(54) Semiconductor device and method of fabricating the same

(75) Inventors: Takao Yamazaki, Tokyo (JP); Naoji Senba, Tokyo (JP); Yuzo Shimada, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/863,077

(22) Filed: May 23, 2001

(30) Foreign Application Priority Data
May 23, 2000 (JP) 2000-152191

(51) Int. Cl. H01L 23/34

(52) U.S. Cl. 257/723

(57) ABSTRACT

A semiconductor device includes (a) a semiconductor chip, (b) a patterned lead composed of an electrical conductor and formed on the semiconductor chip in electrical contact with the semiconductor chip, and (c) a resin film sealing a main surface of the semiconductor chip therewith. The lead has a portion projecting beyond the main surface of the semiconductor chip.

### BACKGROUND OF THE INVENTION

1. Field of the Invention

The invention relates to a semiconductor device and a method of fabricating the same, and more particularly to a semiconductor device which can be vertically stacked one on another and fabricated compact and in low costs, and a method of fabricating such a semiconductor device.

2. Description of the Related Art

There have been suggested a lot of semiconductor devices each including a plurality of semiconductor packages vertically or three-dimensionally stacked one on another. FIGS. 1 and 2 illustrate an example of such a semiconductor device. The illustrated semiconductor device is one suggested in Japanese Patent Publication No. 2765823.

FIG. 2 illustrates a semiconductor package arranged at a lowermost stage, and FIG. 1 illustrates a semiconductor package arranged at stages other than a lowermost stage.

The semiconductor package illustrated in FIG. 1 is comprised of a lead frame 107 having a predetermined pattern and designed bent in a predetermined manner, a semiconductor chip 105 to which the lead frame 107 is adhered through an adhesive 106, a resin package 108 sealing the lead frame 107 and the semiconductor chip 105 therewith, and a bonding wire electrically connecting a bonding pad 101 formed on the semiconductor chip 105, to an inner lead portion 102 of the lead frame 107.

The lead frame 107 is comprised of an external lead portion 109 having a distal end appearing externally of the resin package 108, an inner lead portion 102 at which the lead frame 107 is adhered to the semiconductor chip 105 through an adhesive 106, and a connector portion 103 connecting the inner lead portion 102 and the external lead portion 109 to each other.

The connector portion 103 has an upwardly bending portion appearing at an upper surface of the resin package 108. The upwardly bending portion is supported at a lower surface thereof with a vertical wall 104 having a bottom appearing at a lower surface of the resin package 108.

A plurality of semiconductor packages stacked one on another is electrically and mechanically connected to one another through the connector portion 103 and the vertical wall 104.

The semiconductor package illustrated in FIG. 2 has almost the same structure as the structure of the semiconductor package illustrated in FIG. 1, but further includes an external lead 110 externally extending from the external lead portion 109, and bending towards a bottom of the resin package 108.

A plurality of the semiconductor packages illustrated in FIG. 1 and the semiconductor package illustrated in FIG. 2 are stacked one on another such that the semiconductor package illustrated in FIG. 2 is located lowermost. Those semiconductor packages are electrically and mechanically connected to one another by coating an exposed bottom of the vertical wall 104 with electrically conductive material such as solder or electrically conductive paste, and connecting the electrically conductive material of a first semiconductor package to the connector portion 103 of a second semiconductor package located below the first semiconductor package.

In the above-mentioned semiconductor device illustrated in FIGS. 1 and 2, since the lead frame 107 is designed to externally extend from the semiconductor chip 105, the lead frame 107 is unavoidably greater in size than the semiconductor chip 105 regardless of a size and a thickness of the semiconductor chip 105. In addition, the vertical wall 104 is located remote from the semiconductor chip 105. As a result, the conventional semiconductor device illustrated in FIGS. 1 and 2 is remarkably greater in size than the semiconductor chip 105, and further greater than a standard semiconductor mold package.

The resin package 108 is formed through the use of a mold having a structure in which a portion corresponding to the vertical wall 104 is omitted. Hence, if the vertical wall 104 were to be changed in size, it would take much time to change the mold accordingly.

In addition, since it is quite difficult to have high accuracy at which the vertical wall 104 is to be formed, it would be quite difficult to form the vertical wall 104 at a pitch equal to or smaller than 150 micrometers.

Hence, it would be difficult to fabricate the semiconductor device smaller in size, resulting in that it would be quite difficult to enhance a density at which semiconductor devices are mounted on a substrate.

In addition, since the external leads 109 have free ends which are different from one another in shape, they have to be processed so as to have a uniform shape, resulting in an increase in fabrication costs.

In the conventional semiconductor device, the lead frame 107 is designed to be relatively thick, specifically, about 0.12 mm-thick, resulting in that the semiconductor device is unavoidably thick.

In a semiconductor device comprised of a plurality of semiconductor packages three-dimensionally stacked one on another, it would be necessary for the semiconductor device to have a selector for selecting a semiconductor chip among semiconductor chips of the semiconductor devices. However, the conventional semiconductor device illustrated in FIGS. 1 and 2 is not designed to include such a selector.

If lead frames suitable for each of the semiconductor packages have to be fabricated, steps of forming such lead frames would be unavoidably increased, and it would take much time to actually fabricate such lead frames.

Above all, since the number of the semiconductor device is limited by the number of a semiconductor package having a lowest fabrication yield, a fabrication yield of the semiconductor device would be deteriorated.

Japanese Patent Publication No. 2718647 (Japanese Unexamined Patent Publication No. 8-51127) has suggested a semiconductor device including (a) a plurality of semiconductor packages each having a semiconductor chip including a plurality of bonding pads, a plurality of inner and outer leads, an insulating film on which the semiconductor chip is to be mounted, a resin film for protecting the semiconductor chip and the inner lead such that a lower surface of the semiconductor chip is exposed, (b) a plurality of frames each having a circuit pattern electrically connected to the outer lead of each of the semiconductor packages, (c) a printed circuit board including a land pattern electrically connected to the circuit pattern of each of the frames, and a capacitor mounted on the land pattern located below the exposed lower surface of the semiconductor chip, (d) a plurality of electrically conductive films each formed on the exposed lower surface of the semiconductor chip, and (e) a plurality of ground terminals each electrically connected to each of the electrically conductive films and further electrically connected to the land pattern of the printed circuit board.

Japanese Patent Publication No. 2806357 (Japanese Unexamined Patent Publication No. 9-283697) has suggested a stack module including a plurality of substrates stacked vertically. Each of the substrates includes a semiconductor chip mounted thereon. A wave-shaped heat radiator is sandwiched between a semiconductor chip and an adjacent substrate.

Japanese Unexamined Patent Publication No. 10-144851 has suggested a semiconductor device including a plurality of semiconductor packages stacked one on another, in which each of the semiconductor packages includes a semiconductor chip, and a lead frame adhered to a surface of the semiconductor chip through an adhesive.

Japanese Patent Publication No. 2765572 (Japanese Unexamined Patent Publication No. 10-163414) has suggested a multi-chip semiconductor device including a plurality of semiconductor modules stacked one on another with a spacer being sandwiched between the semiconductor modules. Each of the semiconductor modules includes a semiconductor chip. The semiconductor modules are electrically connected to one another to define a plurality of electrodes. A pattern for electrically connecting the semiconductor chip to the electrode is differently formed for each of the semiconductor modules. The electrode electrically connected to a pattern is designed to act as a chip selector for selecting a semiconductor chip which is to be electrically connected to the pattern.

Japanese Unexamined Patent Publication No. 10-163382 has suggested a semiconductor package including a chip having a plurality of input/output pads, a body in which the chip is sealed, a plurality of leads electrically connected to the input/output pads at one side in the body, and, at the other side, projecting from a lower surface of the body, extending upwardly, and being bent, and a fixer which physically fixes the leads to the chip.

### SUMMARY OF THE INVENTION

In view of the above-mentioned problems in the conventional semiconductor device, it is an object of the present invention to provide a semiconductor device which can be readily stacked one on another, not greater in size than a semiconductor chip, and can be mounted on a substrate at a greater density than conventional ones.

It is also an object of the present invention to provide a method of fabricating such a semiconductor device.

In one aspect of the present invention, there is provided a semiconductor device including (a) a semiconductor chip, (b) a patterned lead composed of an electrical conductor and formed on the semiconductor chip in electrical contact with the semiconductor chip, and (c) a resin film sealing a main surface of the semiconductor chip therewith, the lead having a portion projecting beyond the main surface of the semiconductor chip.

The semiconductor device may further include (d) a first electrode pad formed on the lead at a first end of the lead, (e) a second electrode pad formed on the main surface of the semiconductor chip, and (f) a first electrically conductive bump electrically connecting the first and second electrode pads to each other.

The semiconductor device may further include a first electrically insulating layer formed at a periphery of the main surface of the semiconductor chip, the first electrically insulating layer having a thickness equal to a sum of thicknesses of the first electrode pad, the first electrically conductive bump, and the second electrode pad.

The semiconductor device may further include a second electrically insulating layer formed on the lead.

It is preferable that the resin film is thermoplastic and adhesive.

The semiconductor device may further include a third electrode pad(s) formed on at least one of opposite surfaces of the projecting portion of the lead.

The semiconductor device may further include a third electrically insulating layer formed on a side of the semiconductor chip, in which case, it is preferable that the third electrically insulating layer is formed further on a bottom of the semiconductor chip.

It is preferable that the second electrically insulating layer is formed also on the projecting portion of the lead, the second electrically insulating layer being formed with at least one opening on the projecting portion of the lead, the semiconductor device further comprising a third electrode pad formed in the opening in electrical contact with the lead.

It is preferable that the first electrically insulating layer has a thickness of 50 micrometers of smaller.

It is preferable that the second electrically insulating layer is formed with at least one through-hole through which resin which will make the resin film enters a gap between the lead and the semiconductor chip.

There is further provided a semiconductor device including (a) a semiconductor chip, (b) a patterned lead composed of an electrical conductor and formed on the semiconductor chip in electrical contact with the semiconductor chip, the lead extending along a side and a bottom of the semiconductor chip in electrically insulating condition therebetween, (c) a resin film sealing a main surface of the semiconductor chip therewith, (d) an electrically insulating film formed on the lead and formed with openings facing the side and the bottom of the semiconductor chip, and (e) electrode pads formed in the openings.

There is still further provided a semiconductor device including (a) a semiconductor chip, (b) a patterned lead composed of an electrical conductor and formed on the semiconductor chip in electrical contact with the semiconductor chip, the lead having a portion projecting beyond a main surface of the semiconductor chip, (c) a resin film sealing the main surface of the semiconductor chip therewith, (d) a first electrically insulating film formed on the lead and formed in the portion with at least one opening, (e) a second insulating film formed along a side and a bottom of the semiconductor chip, and (f) an electrode pad formed in the opening.

The semiconductor device may further include a second electrode pad formed on a lower surface of the projecting portion.

It is preferable that the projecting portion of the lead is bent along the side of the semiconductor chip.

There is yet further provided a semiconductor device comprised of a first semiconductor package and a second semiconductor package. The first semiconductor package includes (a) a semiconductor chip, (b) a patterned lead composed of an electrical conductor and formed on the semiconductor chip in electrical contact with the semiconductor chip, the lead extending along a side and a bottom of the semiconductor chip in electrically insulating condition, (c) a resin film sealing a main surface of the semiconductor chip therewith, (d) an electrically insulating film formed on the lead and formed with a first opening facing the side of the semiconductor chip and a second opening facing the bottom of the semiconductor chip, and (e) electrode pads formed in the first and second openings. The second semiconductor package includes (a) a semiconductor chip, (b) a patterned lead composed of an electrical conductor and formed on the semiconductor chip in electrical contact with the semiconductor chip, the lead having a portion projecting beyond a main surface of the semiconductor chip, the projecting portion of the lead being bent along the side of the semiconductor chip, (c) a resin film sealing the main surface of the semiconductor chip therewith, (d) a first insulating film formed on the lead and formed in the portion with at least one opening, (e) a second insulating film formed along a side and a bottom of the semiconductor chip, (f) an electrode pad formed in the opening, and (g) a second electrode pad formed on a lower surface of the projecting portion. The second electrode of the second semiconductor package makes electrical contact with the electrode pad of the first semiconductor package, formed in the first opening, thereby the first and second semiconductor packages being electrically connected to each other.

There is still yet further provided a semiconductor device including (a) a plurality of semiconductor packages stacked vertically one on another, and (b) electrically conductive bumps electrically connecting vertically adjacent semiconductor packages to each other, each of the semiconductor packages including (a1) a semiconductor chip, (a2) a patterned lead composed of an electrical conductor and formed on the semiconductor chip in electrical contact with the semiconductor chip, the lead having a portion projecting beyond a main surface of the semiconductor chip, (a3) a resin film sealing the main surface of the semiconductor chip therewith, the electrically conductive bumps being sandwiched between a lower surface of the projecting portion of a first semiconductor package and an upper surface of the projecting portion of a second semiconductor package located just below the first semiconductor package.

There is further provided a semiconductor device comprised of a plurality of semiconductor packages stacked vertically one on another, each of the semiconductor packages including (a1) a semiconductor chip, and (a2) a patterned lead composed of an electrical conductor and formed on the semiconductor chip in electrical contact with the semiconductor chip, the lead having a portion projecting beyond a main surface of the semiconductor chip, the portion being bent along a side of the semiconductor chip, the portion of a first semiconductor package being in electrical contact with the portion of a second semiconductor package located just below the first semiconductor package, thereby the first and second semiconductor packages being electrically connected to each other.

There is further provided a semiconductor device including (a) a plurality of semiconductor packages stacked vertically one on another, and (b) a connector electrically connecting the semiconductor packages to one another, each of the semiconductor packages including (a1) a semiconductor chip, and (a2) a patterned lead composed of an electrical conductor and formed on the semiconductor chip in electrical contact with the semiconductor chip, the lead having a portion projecting beyond a main surface of the semiconductor chip, the portion being bent along a side of the semiconductor chip, the connector making electrical contact with the portion of each of the semiconductor packages, thereby the semiconductor packages being electrically connected to one another through the connector.

In another aspect of the present invention, there is provided a method of fabricating a semiconductor device, including the steps of (a) forming a first electrode pad on a lower surface of a lead, (b) forming a second electrode pad and a first insulating layer on a main surface of a semiconductor chip, the lead having a portion projecting beyond the main surface of the semiconductor chip, (c) forming a first electrically conductive bump on at least one of the first and second electrode pads, the first insulating layer having a thickness equal to a sum of thicknesses of the first electrode, the second electrode and the first electrically conductive bump, (d) coupling the semiconductor chip and the lead to each other by thermal compression or re-flowing of the first electrically conductive bump, (e) sealing the main surface of the semiconductor chip with resin, and (f) forming a third electrode pad on at least one of upper and lower surfaces of the projecting portion.

The method may further include the step of forming a second electrically conductive bump on a lower surface of the projection portion of the lead.

There is further provided a method of fabricating a semiconductor device, including the steps of (a) forming a first electrically insulating layer on a wafer, on which a semiconductor device has been fabricated, around the semiconductor device, (b) forming a first electrode pad on the wafer, (c) forming a first electrically conductive bump on the first electrode pad, (d) connecting the first electrode to a second electrode formed on a lead at its end by carrying out thermal compression or re-flowing of the first electrically conductive bump at a time in the entirety of the wafer, (e) sealing the wafer and the lead with resin, and (f) cutting the semiconductor device and the lead at a lower surface of the wafer into individual semiconductor devices.

The advantages obtained by the aforementioned present invention will be described hereinbelow.

In accordance with the present invention, it is possible to design a lead to have almost the same size as a size of a semiconductor chip, and to design both a lead and a resin package to have a small thickness. This ensures that the semiconductor device could have the almost the same size as a size of a semiconductor chip, and hence, could have a small size which makes it possible to mount the semiconductor device on a substrate at a greater density.

The semiconductor devices can be readily stacked one on another by thermally compressing or re-flowing the electrically conductive bumps at a time, by electrically connecting the leads bent along a side of a semiconductor chip, to each other, or by electrically connecting the bent leads to one another through another an electrically conductive connector.

An electrically insulating film to be formed on a semiconductor chip preferably has a thickness equal to a sum of thicknesses of an electrode pad formed on the semiconductor chip, an electrode pad formed on the lead, and an electrically conductive bump to be sandwiched between those electrode pads. The insulating film electrically insulates the lead and the semiconductor chip from each other, and keeps the lead flat even after the lead has been connected to the semiconductor chip.

There is formed a gap between the lead and the semiconductor chip. The insulating film ensures that resin enters the gap to thereby fix the lead.

The above and other objects and advantageous features of the present invention will be made apparent from the following description made with reference to the accompanying drawings, in which like reference characters designate the same or similar parts throughout the drawings.

### BRIEF DESCRIPTION OF THE DRAWINGS

FIG. 1 is a cross-sectional view of a conventional semiconductor device.

FIG. 2 is a cross-sectional view of a conventional semiconductor device.

FIG. 3 is a cross-sectional view of a semiconductor device in accordance with the first embodiment of the present invention.

FIG. 4 is a cross-sectional view of a semiconductor device in accordance with the second embodiment of the present invention.

FIG. 5 is a cross-sectional view of a semiconductor device in accordance with the third embodiment of the present invention.

FIG. 6 is a top plan view of a lead in the third embodiment.

FIG. 7 is a cross-sectional view of a semiconductor device in accordance with the fourth embodiment of the present invention.

FIG. 8A is a cross-sectional view of a semiconductor device in accordance with the fifth embodiment of the present invention.

FIG. 8B is a cross-sectional view of a semiconductor device in accordance with the fifth embodiment.

FIG. 9A is a cross-sectional view of a semiconductor device in accordance with the sixth embodiment of the present invention.

FIG. 9B is a cross-sectional view of a semiconductor device in accordance with the sixth embodiment.

FIG. 10 is a cross-sectional view of a semiconductor device in accordance with the seventh embodiment of the present invention.

FIGS. 11A to 11I are cross-sectional views of a semiconductor device in accordance with the eighth embodiment of the present invention, illustrating respective steps of a method of fabricating the same.

FIG. 12 is a top plan view illustrating an electrically conductive pattern used in the eighth embodiment.

### DESCRIPTION OF THE PREFERRED EMBODIMENTS

Preferred embodiments in accordance with the present invention will be explained hereinbelow with reference to drawings.

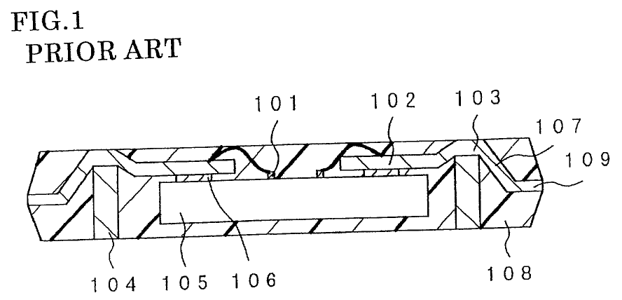

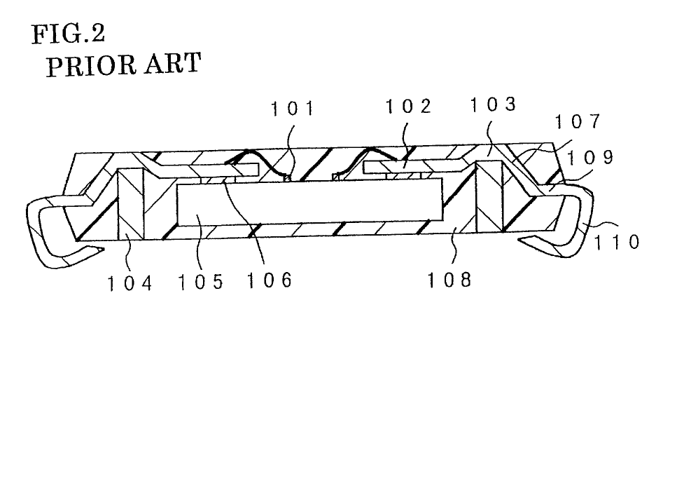

FIG. 1 is a cross-sectional view of a semiconductor device 100 in accordance with the first embodiment.

The semiconductor device 100 is comprised of a semiconductor chip 1, two leads 2 formed above the semiconductor chip 1, first electrode pads 3a formed on a lower surface of each of the leads 2 at a first end of the leads 2, second electrode pads 3d formed on a main surface of the semiconductor chip 1 in alignment with the first electrode pads 3a, first electrically conductive bumps 4 electrically connecting the first and second electrode pads 3a and 3d to each other, first electrically insulating layers 6 which is formed at a periphery of the main surface of the semiconductor chip 1 and which supports the leads 2 therewith, and a resin film 5 sealing a main surface of the semiconductor chip 1 therewith.

Each of the leads 2 is composed of an electrical conductor such as Cu or Al, and is designed to have a portion 2a projecting beyond the main surface of the semiconductor chip 1. The leads 2 is arranged in symmetry about a center of the semiconductor chip, and have a thickness equal to or smaller than 100 micrometers.

The first electrically conductive bumps 4 may be composed of Au or Sn-Pb alloy. The electrode pads 3a and 3d are connected to each other through the first electrically conductive bumps by thermally compressing or re-flowing the first electrically conductive bumps 4 at a temperature in the range of about 150 to 350 degrees centigrade in dependence on a material of which the first electrically conductive bumps 4 is composed.

The first electrically insulating layer 6 has a thickness equal to a sum of thicknesses of the first electrode pad 3a, the first electrically conductive bump 4, and the second electrode pad 3d. Thus, the first electrically insulating layer 6 maintains flatness of the leads 2 even after the leads 2 have been connected to the semiconductor chip 1. Specifically, the first electrically insulating layer 6 has a thickness equal to or smaller than 50 micrometers.

The first electrically insulating layer 6 is composed of an electrically insulating resin such as polyimide, thermoplastic adhesive resin or resist. The first electrically insulating layer 6 is formed on the semiconductor chip 1 by photolithography and etching before the leads 2 are connected to the semiconductor chip 1. As an alternative, the first electrically insulating layer 6 may be formed by coating or applying an electrically insulating resin film to an entire surface of the leads, and then, by etching the resin film to thereby remove extra portions of the resin film.

A gap between the semiconductor chip 1 and the leads 2, and the leads 2 are sealed with the resin film 5 composed of epoxy resin or thermoplastic adhesive resin, for instance.

Third electrode pads 3b are formed on upper surfaces of the projecting portions 2a of the leads 2, and fourth electrodes 3c are formed on lower surfaces of the projecting portions 2a of the leads 2.

The first, third and fourth electrode pads 3a, 3b and 3c are plated wit Ni/Au or Pd.

Second electrically conductive bumps 7 are formed below the fourth electrodes 3c in electrical contact with the fourth electrodes 3c. The second electrically conductive bumps 7 are composed of an alloy such as Sn-Pb alloy, Sn-Zn alloy or Sn-Ag alloy.

In accordance with the semiconductor device 100, it would be possible to design the leads to have the almost the same size as a size of the semiconductor chip 1, ensuring that the semiconductor device 100 has almost the same size as a size of the semiconductor chip 1. Accordingly, a plurality of the semiconductor devices 100 may be arranged on a substrate at a greater density than conventional ones.

In addition, since the second electrically conductive bumps 7 can be connected to the third electrode pads 3c at a time by thermal compression or re-flow process, a plurality of the semiconductor chips 1 can be mounted on a substrate at a time, ensuring enhancement in a fabrication yield of the semiconductor device 100.

FIG. 4 is a cross-sectional view of a semiconductor device 110 in accordance with the second embodiment.

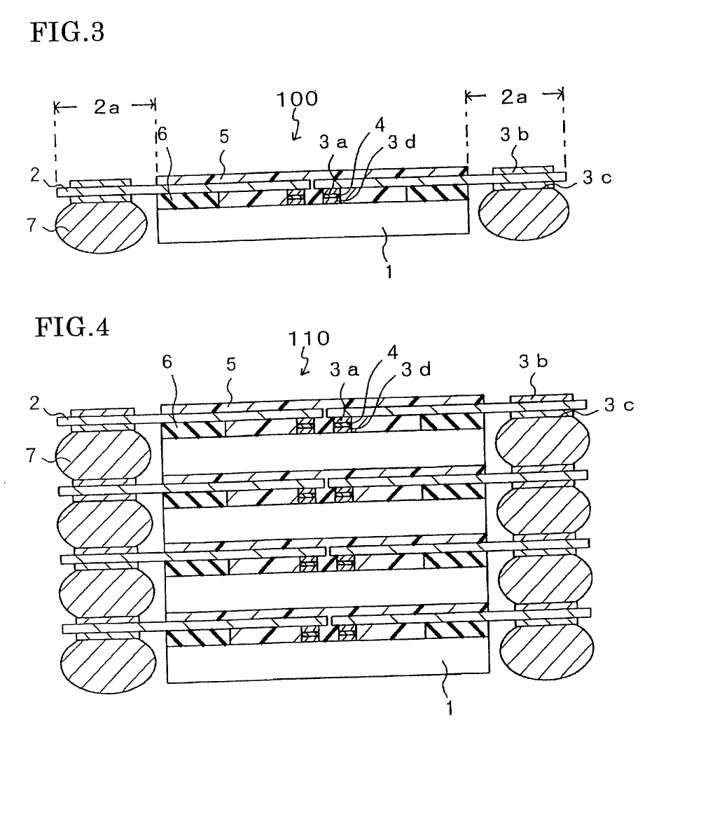

The semiconductor device 110 is comprised of the four semiconductor devices 100 in accordance with the first embodiment, illustrated in FIG. 3, stacked vertically one on another. The semiconductor devices 100 are connected to one another through the second electrically conductive bumps 7. Specifically, a first semiconductor device 100 is connected to a second semiconductor device 100 located just below the first semiconductor device by re-flowing the second electrically conductive bumps 7 at a temperature in the range of 150 to 250 degrees centigrade between the fourth electrode pads 3c of the first semiconductor device 100 and the third electrode pads 3b of the second semiconductor device.

In accordance with the semiconductor device 110, vertically adjacent semiconductor devices 100 are electrically connected to each other through the second electrically conductive bumps 7 sandwiched between the fourth electrode pad 3c of an upper semiconductor device and the third electrode pad 3b of a lower semiconductor device. This ensures a small-sized semiconductor device having a three-dimensional multi-stacked structure, which can be arranged on a substrate at a greater density than a density at which conventional semiconductor devices are arranged on a substrate.

In addition, since the second electrically conductive bumps 7 can be connected to the electrode pads 3c and 3d at a time by thermal compression or reflow process, it would be possible to readily electrically connect the leads 2 of the stacked semiconductor devices 100 to one another.

Though the semiconductor device 110 is comprised of the four semiconductor devices 100 in the fourth embodiment, the semiconductor device 110 may be comprised of one, two, three, five or greater semiconductor devices 100.

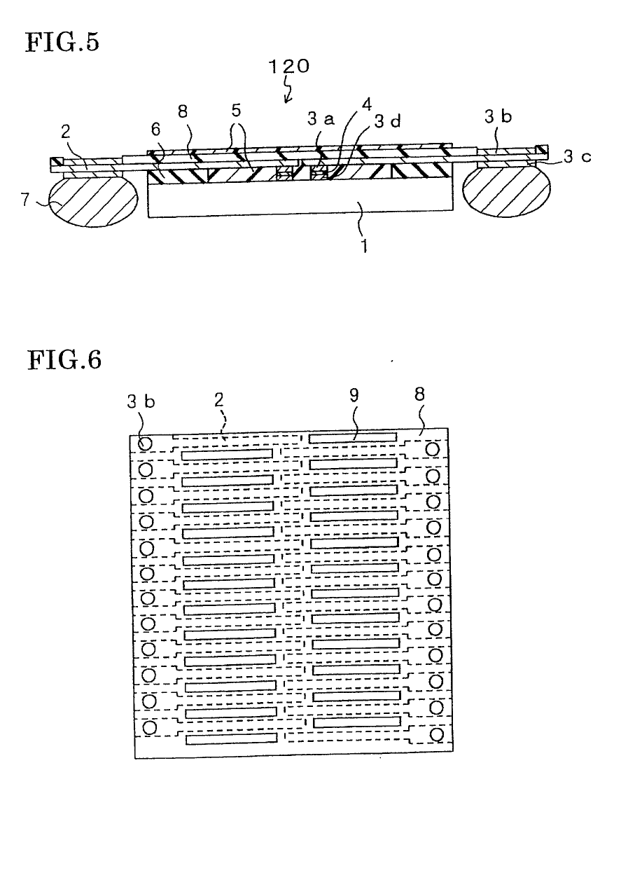

FIG. 5 is a cross-sectional view of a semiconductor device 120 in accordance with the third embodiment.

The semiconductor device 120 is comprised of a semiconductor chip 1, two leads 2 formed above the semiconductor chip 1, first electrode pads 3a formed on a lower surface of each of the leads 2 at a first end of the leads 2, second electrode pads 3d formed on a main surface of the semiconductor chip 1 in alignment with the first electrode pads 3a, first electrically conductive bumps 4 electrically connecting the first and second electrode pads 3a and 3d to each other, first electrically insulating layers 6 which is formed at a periphery of the main surface of the semiconductor chip 1 and which supports the leads 2 therewith, a resin film 5 sealing a main surface of the semiconductor chip 1 therewith, and a second electrically insulating layer 8 formed entirely on the leads 2.

Third electrode pads 3b are formed on upper surfaces of the projecting portions 2a of the leads 2, and fourth electrodes 3c are formed on lower surfaces of the projecting portions 2a of the leads 2. Second electrically conductive bumps 7 are formed below the fourth electrodes 3c in electrical contact with the fourth electrodes 3c.

That is, the semiconductor device 120 is structurally different from the semiconductor device 100 illustrated in FIG. 3 in further including the second electrically insulating layer 8.

The second electrically insulating layer 8 is composed of polyimide, for instance, and has a thickness equal to or smaller than 50 micrometers.

The second electrically insulating layer 8 is formed with openings on the projecting portion 2a of the leads 2 by lithography and etching, or by application of laser beams. The third electrode pads 3b are formed in the openings.

The semiconductor device 120 in accordance with the third embodiment provides the same advantages provided by the semiconductor device 100 in accordance with the first embodiment. In addition, the second electrically insulating layer 8 keeps flatness of the leads 2, and makes it easy to bend the leads 2.

FIG. 6 is a top plan view of the semiconductor device 120. As illustrated in FIG. 6, the leads 2 may be arranged so that the leads 2 are offset each other. As an alternative, the lead 2 may be arranged in alignment.

In addition, the second electrically insulating layer 8 is formed with elongate rectangular openings 9 through which a resin can readily enter a gap formed between the leads 2 and the semiconductor chip 1.

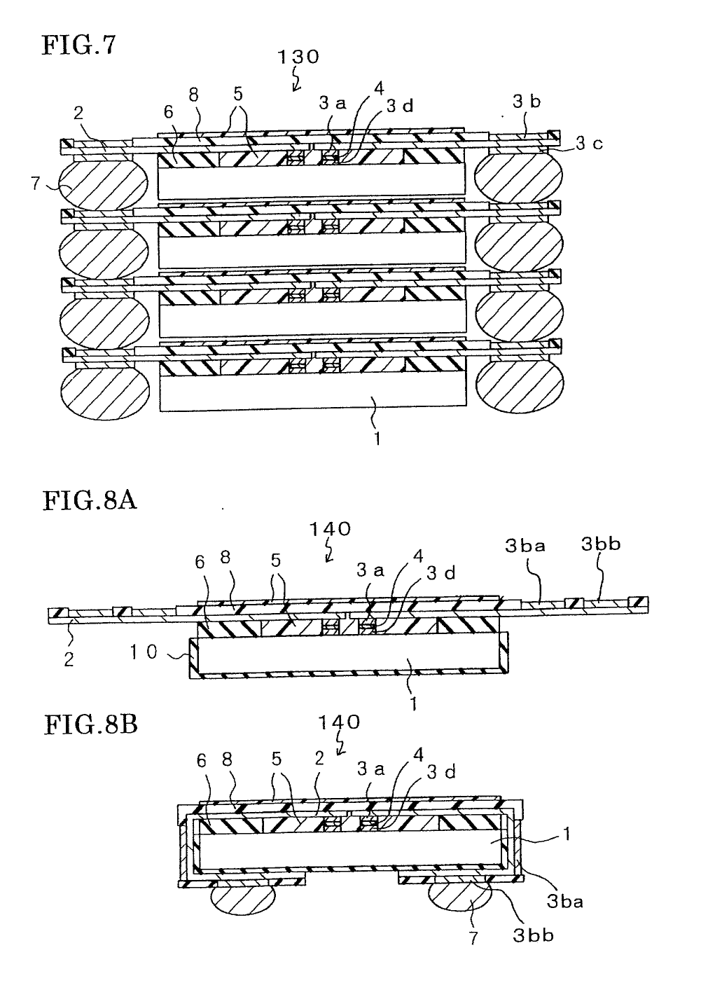

FIG. 7 is a cross-sectional view of a semiconductor device 130 in accordance with the fourth embodiment.

The semiconductor device 130 is comprised of the four semiconductor devices 120 in accordance with the third embodiment, illustrated in FIG. 5, stacked vertically one on another. The semiconductor devices 130 are connected to one another through the second electrically conductive bumps 7. Specifically, a first semiconductor device 130 is connected to a second semiconductor device 130 located just below the first semiconductor device by re-flowing the second electrically conductive bumps 7 at a temperature in the range of 150 to 250 degrees centigrade between the fourth electrode pads 3c of the first semiconductor device 120 and the third electrode pads 3b of the second semiconductor device 120.

In accordance with the semiconductor device 130, vertically adjacent semiconductor devices 120 are electrically connected to each other through the second electrically conductive bumps 7 sandwiched between the fourth electrode pad 3c of an upper semiconductor device and the third electrode pad 3b of a lower semiconductor device. This ensures a small-sized semiconductor device having a three-dimensional multi-stacked structure, which can be arranged on a substrate at a greater density than a density at which conventional semiconductor devices are arranged on a substrate.

In addition, since the second electrically conductive bumps 7 can be connected to the electrode pads 3c and 3d at a time by thermal compression or re-flow process, it would be possible to readily electrically connect the leads 2 of the stacked semiconductor devices 120 to one another.

Though the semiconductor device 130 is comprised of the four semiconductor devices 120 in the fourth embodiment, the semiconductor device 130 may be comprised of one, two, three, five or greater semiconductor devices 120.

FIGS. 8A is a cross-sectional view of an intermediate product of a semiconductor device 140 in accordance with the fifth embodiment, and FIG. 8B is a cross-sectional view of a final product of the semiconductor 140.

With reference to FIG. 8A, an intermediate product of the semiconductor device 140 is comprised of a semiconductor chip 1, two leads 2 formed above the semiconductor chip 1, first electrode pads 3a formed on a lower surface of each of the leads 2 at a first end of the leads 2, second electrode pads 3d formed on a main surface of the semiconductor chip 1 in alignment with the first electrode pads 3a, first electrically conductive bumps 4 electrically connecting the first and second electrode pads 3a and 3d to each other, first electrically insulating layers 6 which is formed at a periphery of the main surface of the semiconductor chip 1 and which supports the leads 2 therewith, a resin film 5 sealing a main surface of the semiconductor chip 1 therewith, a second electrically insulating layer 8 formed entirely on the leads 2, and a third electrically insulating layer 10 covering a side and a bottom of the semiconductor chip 1 therewith.

Each of the leads 2 is designed to have a portion 2a projecting beyond a main surface of the semiconductor chip 1.

The second electrically insulating layer 8 is formed with openings on the projecting portions 2a. Third electrode pads 3ba and 3bb are formed in the openings of the second electrically insulating layer 8.

After an intermediate product of the semiconductor device 140 has been fabricated as illustrated in FIG. 8A, the projecting portions 2a of the leads 2 together with the second electrically insulating layer 8 are bent along a side and a bottom of the semiconductor chip 1, as illustrated in FIG. 8B. Then, the second electrically conductive bumps 7 are formed below the third electrode pads 3bb in contact with the third electrode pads 3bb.

Thus, a final product of the semiconductor device 140 is completed as illustrated in FIG. 8B.

In accordance with the semiconductor device 140, since the projecting portions 2a of the leads 2 are bent along a side and a bottom of the semiconductor chip 1, the semiconductor device 140 can be fabricated smaller in size than the semiconductor device 120 in accordance with the third embodiment, illustrated in FIG. 5.

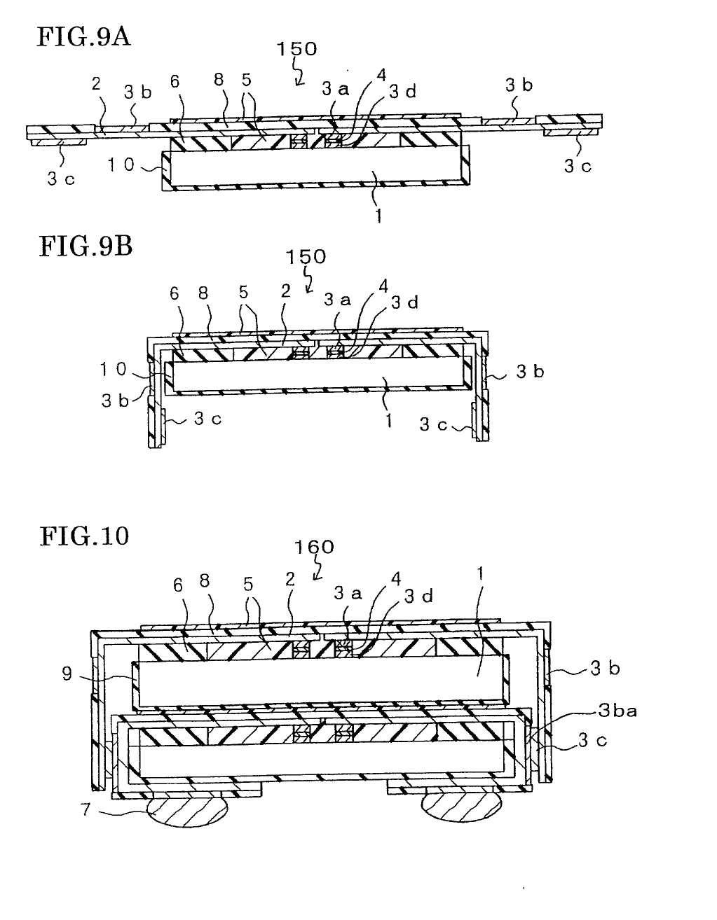

FIGS. 9A is a cross-sectional view of an intermediate product of a semiconductor device 150 in accordance with the sixth embodiment, and FIG. 8B is a cross-sectional view of a final product of the semiconductor 150.

With reference to FIG. 9A, an intermediate product of the semiconductor device 140 is comprised of a semiconductor chip 1, two leads 2 formed above the semiconductor chip 1, first electrode pads 3a formed on a lower surface of each of the leads 2 at a first end of the leads 2, second electrode pads 3d formed on a main surface of the semiconductor chip 1 in alignment with the first electrode pads 3a, first electrically conductive bumps 4 electrically connecting the first and second electrode pads 3a and 3d to each other, first electrically insulating layers 6 which is formed at a periphery of the main surface of the semiconductor chip 1 and which supports the leads 2 therewith, a resin film 5 sealing a main surface of the semiconductor chip 1 therewith, a second electrically insulating layer 8 formed entirely on the leads 2, and a third electrically insulating layer 10 covering a side and a bottom of the semiconductor chip 1 therewith.

Each of the leads 2 is designed to have a portion 2a projecting beyond a main surface of the semiconductor chip 1.

The second electrically insulating layer 8 is formed with openings on the projecting portions 2a. Third electrode pads 3b are formed in the openings of the second electrically insulating layer 8 and on the projecting portions 2a of the leads 2. A fourth electrode pad 3c is formed on a lower surface of the projecting portion 2a of each of the leads 2.

After an intermediate product of the semiconductor device 150 has been fabricated as illustrated in FIG. 9A, the projecting portions 2a of the leads 2 together with the second electrically insulating layer 8 are bent downwardly along a side of the semiconductor chip 1, as illustrated in FIG. 9B. The semiconductor device 150 does not include the second electrically conductive bumps 7 unlike the semiconductor device 140 in accordance with the fifth embodiment, illustrated in FIG. 8B.

Thus, a final product of the semiconductor device 150 is completed as illustrated in FIG. 9B.

In accordance with the semiconductor device 150, since the projecting portions 2a of the leads 2 are bent downwardly along a side of the semiconductor chip 1, the semiconductor device 150 can be fabricated smaller in horizontal length than the semiconductor device 120 in accordance with the third embodiment, illustrated in FIG. 5.

FIG. 10 is a cross-sectional view of a semiconductor device 160 in accordance with the seventh embodiment.

The semiconductor device 160 is comprised of a combination of the semiconductor device 140 in accordance with the fifth embodiment, illustrated in FIG. 8B, and the semiconductor device 150 in accordance with the sixth embodiment, illustrated in FIG. 9B. Specifically, the semiconductor device 150 is stacked on the semiconductor device 140.

The semiconductor devices 150 and 140 are electrically connected to each other by thermally compressing the fourth electrode pad 3c of the semiconductor pad 150 to the third electrode pad 3ba of the semiconductor device 140. For instance, the electrode pads 3ba and 3c are composed of Ni-Au alloy or Pd.

As an alternative, the semiconductor devices 150 and 140 may be electrically connected to each other by forming an Au stud bump on the electrode pads 3ba and/or 3c, and then, by thermally compressing the electrode pads 3ba and 3c to each other through the Au stud bump.

The semiconductor devices 150 illustrated in FIG. 9B may be further stacked on the semiconductor device 160 to fabricate a multi-staged semiconductor device, in which case, the fourth electrode pad 3c of an upper semiconductor device 150 is electrically connected to the third electrode pad 3b of a lower semiconductor device 150.

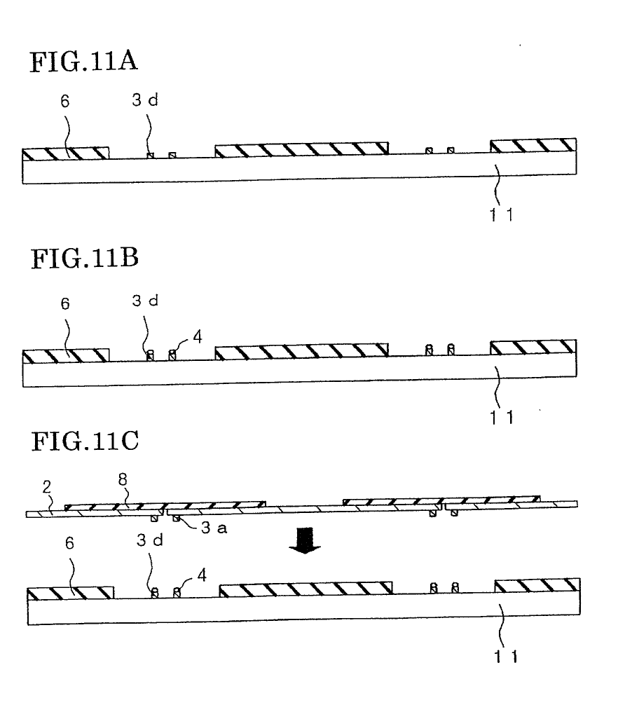

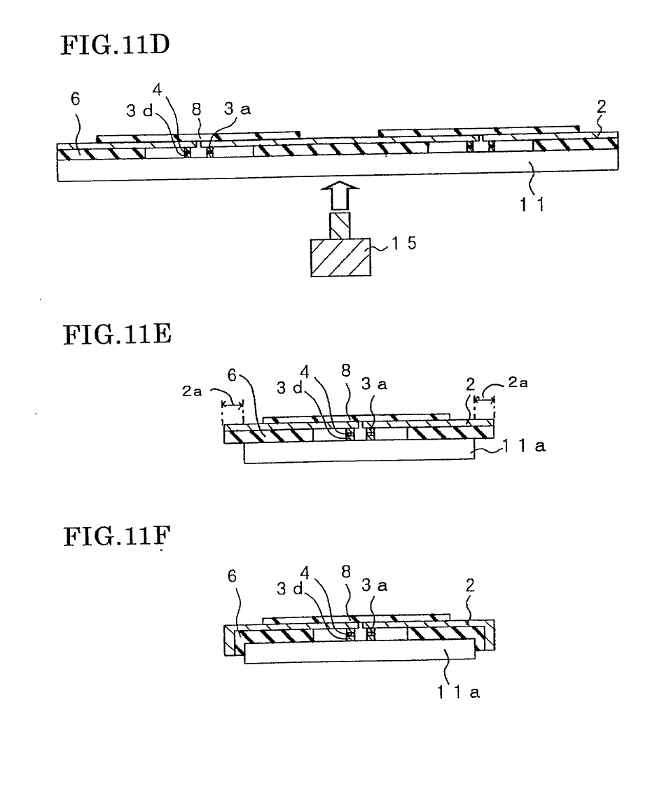

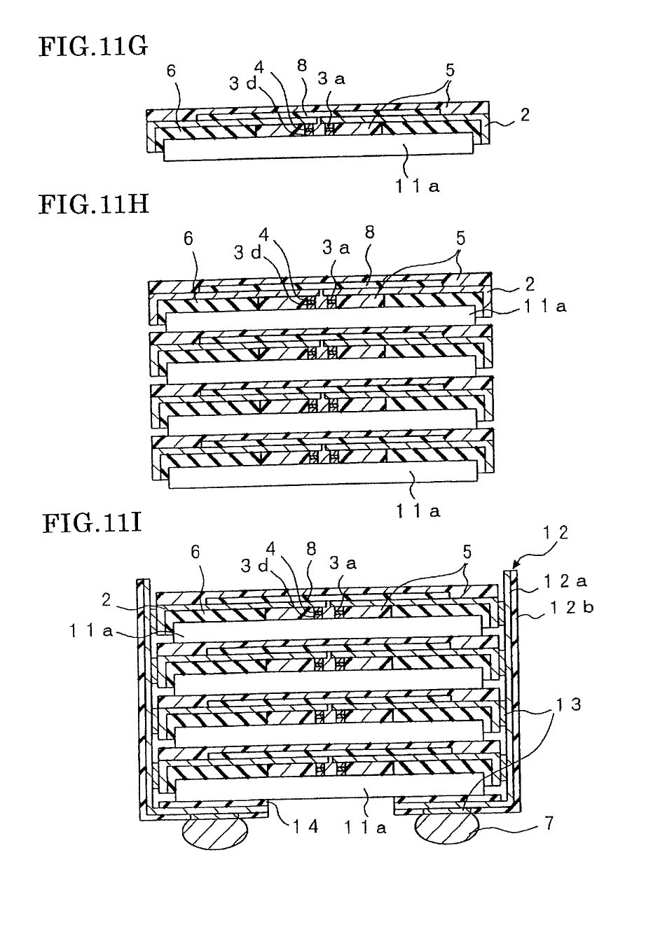

FIGS. 11A to 11I are cross-sectional views of a semiconductor device in accordance with the eighth embodiment, illustrating respective steps of a method of fabricating the same.

As illustrated in FIG. 11A, a first electrically insulating layer 6 is formed on a semiconductor wafer 11 around an area where a chip is to be fabricated. The first electrically insulating layer 6 has a thickness equal to a sum of thicknesses of later mentioned first electrode pad 3a, second electrode pad 3d, and first electrically conductive bump 4, and equal to or smaller than 50 micrometers. The first electrically insulating layer 6 is composed of thermoplastic and adhesive resin.

Then, second electrode pads 3d are formed on the semiconductor wafer 11 in an area where a chip is to be fabricated.

Then, as illustrated in FIG. 11B, first electrically conductive bumps 4 such as Au stud bumps are formed on the first electrode pads 3d.

As illustrated in FIG. 11C, a plurality of leads 2 are horizontally coupled to one another through second electrically insulating layers 8 formed bridging over upper surfaces of the adjacent leads 2. Each of the leads 2 is formed on a lower surface thereof with first electrode pads 3a.

The leads 2 are aligned onto the semiconductor wafer 11 such that the first electrode pads 3a are in alignment with the first electrically conductive bumps 4.

Then, the leads 2 are coupled to the semiconductor wafer 11 by concurrently thermally compressing the first electrode pads 3a and the first electrically conductive bumps 4 to each other, or by re-flowing the first electrically conductive bumps 4.

The second electrically insulating layer 8 is preferably formed with the openings 9 in such a pattern as illustrated in FIG. 6 in order to facilitate a resin to enter a gap to be formed between the semiconductor wafer 11 and the leads 2.

Then, as illustrated in FIG. 11D, the semiconductor wafer 11 is cut at a lower surface thereof by means of a dicer 15 such that the leads 2 project beyond the semiconductor wafer 11.

As a result, the semiconductor wafer 11 is divided into individual semiconductor chips lla, as illustrated in Fig. lE. The leads 2 have a portion 2a projecting beyond a main surface of the semiconductor chip 11a.

Then, as illustrated in FIG. 11F, the projecting portions 2a together with the first electrically insulating layer 6 is bent along a side of the semiconductor chip 11a, and then, fixed to the semiconductor chip 11a by thermal compression.

Then, as illustrated in FIG. 11G, a gap formed between the semiconductor chip 11a and the leads is filled with a resin film 5, and then, the leads 2 and the second electrically insulating film 8 are covered with the resin film 5.

The resin film 5 is preferably composed of thermoplastic and adhesive rein so as to readily couple upper and lower semiconductor packages to each other when a plurality of semiconductor packages are stacked one on another.

Then, as illustrated in FIG. 11H, the semiconductor packages illustrated in Fig 11G are vertically stacked one on another, and thereafter, the semiconductor packages are mechanically coupled to one another by thermally compressing or re-flowing them at a temperature in the range of 150 to 250 degrees centigrade.

In FIG. 11H, four semiconductor packages are stacked, for instance. However, two, three, five or more semiconductor packages may be stacked.

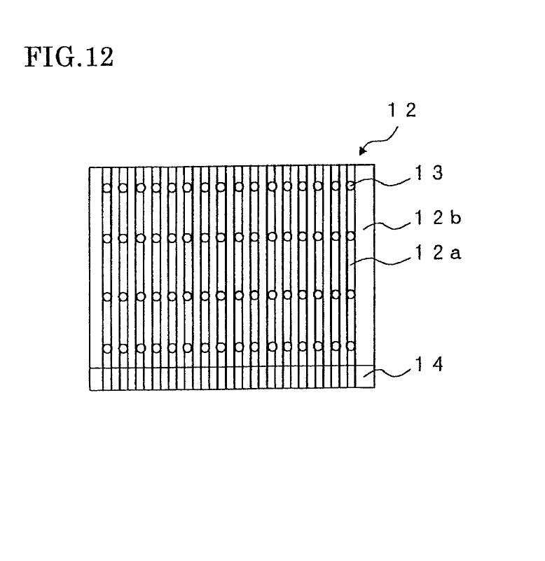

Then, there is prepared a connector 12 as illustrated in FIG. 12. The connector 12 is comprised of an electrically insulating sheet 12b, a plurality of leads 12a arranged on the electrically insulating sheet 12b in parallel with one another, four electrode pads 13 formed on each of the leads 12a, and an electrically insulating layer 14 formed at one end of the electrically insulating sheet 12b, covering ends of the leads 2 therewith.

The electrically insulating sheet 12b is formed with openings below the electrically insulating layer 14. The electrode pads 13 are also formed in the openings in electrical contact with the leads 12a (see FIG. 11I).

Then, as illustrated in FIG. 11I, the electrode pads 13 of the connector 12 are aligned to the projecting portions 2a of the leads, which are now bent along a side of the semiconductor chips 11a, and are coupled to the projecting portions 2a by thermal compression.

For instance, by composing the electrically insulating sheet 12b of thermoplastic and adhesive resin, the connector 12 can be bent along a bottom of the lowermost semiconductor package, and adhered to the bottom by carrying out thermal compression at a temperature in the range of 150 to 250 degrees centigrade.

The electrically insulating layer 14 is sandwiched between the connector 12 and the semiconductor chip 11a to thereby electrically insulate them from each other.

Then, electrically conductive bumps 7 are formed below the electrode pads 13 formed in the electrically insulating sheet 12b and below the electrically insulating layer 14, in electrical contact with the electrode pads 13 by re-flow process. The electrically conductive bumps 7 are composed of Sn-Pb alloy or Sn-Zn alloy, for instance.

Thus, there is completed the semiconductor device in accordance with the eighth embodiment, illustrated in FIG. 11I.

While the present invention has been described in connection with certain preferred embodiments, it is to be understood that the subject matter encompassed by way of the present invention is not to be limited to those specific embodiments. On the contrary, it is intended for the subject matter of the invention to include all alternatives, modifications and equivalents as can be included within the spirit and scope of the following claims.

The entire disclosure of Japanese Patent Application No. 2000-152191 filed on May 23, 2000 including specification, claims, drawings and summary is incorporated herein by reference in its entirety.

What is claimed is:

1. A semiconductor device comprising:
(a) a semiconductor chip;
(b) a patterned lead composed of an electrical conductor and formed on said semiconductor chip in electrical contact with said semiconductor chip; and
(c) a resin film sealing a main surface of said semiconductor chip therewith,
said lead having a portion projecting beyond said main surface of said semiconductor chip.

2. The semiconductor device as set forth in claim 1, further comprising:
(d) a first electrode pad formed on said lead at a first end of said lead;
(e) a second electrode pad formed on said main surface of said semiconductor chip; and
(f) a first electrically conductive bump electrically connecting said first and second electrode pads to each other.

3. The semiconductor device as set forth in claim 2, further comprising a first electrically insulating layer formed at a periphery of said main surface of said semiconductor chip, said first electrically insulating layer having a thickness equal to a sum of thicknesses of said first electrode pad, said first electrically conductive bump, and said second electrode pad.

4. The semiconductor device as set forth in claim 1, further comprising a second electrically insulating layer formed on said lead.

5. The semiconductor device as set forth in claim 1, wherein said resin film is thermoplastic and adhesive.

6. The semiconductor device as set forth in claim 1, further comprising a third electrode pad(s) formed on at least one of opposite surfaces of said projecting portion of said lead.

7. The semiconductor device as set forth in claim 1, further comprising a third electrically insulating layer formed on a side of said semiconductor chip.

8. The semiconductor device as set forth in claim 7, wherein said third electrically insulating layer is formed further on a bottom of said semiconductor chip.

9. The semiconductor device as set forth in claim 4, wherein said second electrically insulating layer is formed also on said projecting portion of said lead, said second electrically insulating layer being formed with at least one opening on said projecting portion of said lead,
said semiconductor device further comprising a third electrode pad formed in said opening in electrical contact with said lead.

10. The semiconductor device as set forth in claim 3, wherein said first electrically insulating layer has a thickness of 50 micrometers of smaller.

11. The semiconductor device as set forth in claim 4, wherein said second electrically insulating layer is formed with at least one through-hole through which resin which will make said resin film enters a gap between said lead and said semiconductor chip.

12. A semiconductor device comprising:
(a) a semiconductor chip;
(b) a patterned lead composed of an electrical conductor and formed on said semiconductor chip in electrical contact with said semiconductor chip, said lead extending along a side and a bottom of said semiconductor chip in electrically insulating condition therebetween;
(c) a resin film sealing a main surface of said semiconductor chip therewith;
(d) an electrically insulating film formed on said lead and formed with openings facing said side and said bottom of said semiconductor chip; and
(e) electrode pads formed in said openings.

13. The semiconductor device as set forth in claim 12, further comprising:
(d) a first electrode pad formed on said lead at a first end of said lead;
(e) a second electrode pad formed on said main surface of said semiconductor chip; and
a first electrically conductive bump electrically connecting said first and second electrode pads to each other.

14. The semiconductor device as set forth in claim 13, further comprising a first electrically insulating layer formed at a periphery of said main surface of said semiconductor chip, said first electrically insulating layer having a thickness equal to a sum of thicknesses of said first electrode pad, said first electrically conductive bump, and said second electrode pad.

15. The semiconductor device as set forth in claim 12, wherein said resin film is thermoplastic and adhesive.

16. The semiconductor device as set forth in claim 12, further comprising a second electrically insulating layer formed on a side of said semiconductor chip.

17. The semiconductor device as set forth in claim 16, wherein said second electrically insulating layer is formed further on a bottom of said semiconductor chip.

18. A semiconductor device comprising:
(a) a semiconductor chip;
(b) a patterned lead composed of an electrical conductor and formed on said semiconductor chip in electrical contact with said semiconductor chip, said lead having a portion projecting beyond a main surface of said semiconductor chip;
(c) a resin film sealing said main surface of said semiconductor chip therewith;
(d) a first electrically insulating film formed on said lead and formed in said portion with at least one opening;
(e) a second insulating film formed along a side and a bottom of said semiconductor chip; and
(f) an electrode pad formed in said opening.

19. The semiconductor device as set forth in claim 18, further comprising a second electrode pad formed on a lower surface of said projecting portion.

20. The semiconductor device as set forth in claim 18, wherein said projecting portion of said lead is bent along said side of said semiconductor chip.

21. The semiconductor device as set forth in claim 18, further comprising:
(d) a first electrode pad formed on said lead at a first end of said lead;
(e) a second electrode pad formed on said main surface of said semiconductor chip; and
(f) a second electrically conductive bump electrically connecting said first and second electrode pads to each other.

22. The semiconductor device as set forth in claim 21, further comprising a third electrically insulating layer formed at a periphery of said main surface of said semiconductor chip, said third electrically insulating layer having a thickness equal to a sum of thicknesses of said first electrode pad, said second electrically conductive bump, and said second electrode pad.

23. The semiconductor device as set forth in claim 18, wherein said resin film is thermoplastic and adhesive.

24. The semiconductor device as set forth in claim 22, wherein said third electrically insulating layer has a thickness of 50 micrometers of smaller.

25. The semiconductor device as set forth in claim 18, wherein said first electrically insulating layer is formed with at least one through-hole through which resin which will make said resin film enters a gap between said lead and said semiconductor chip.

26. A semiconductor device comprising a first semiconductor package and a second semiconductor package,
said first semiconductor package including:
(a) a semiconductor chip;
(b) a patterned lead composed of an electrical conductor and formed on said semiconductor chip in electrical contact with said semiconductor chip, said lead extending along a side and a bottom of said semiconductor chip in electrically insulating condition;
(c) a resin film sealing a main surface of said semiconductor chip therewith;
(d) an electrically insulating film formed on said lead and formed with a first opening facing said side of said semiconductor chip and a second opening facing said bottom of said semiconductor chip; and
(e) electrode pads formed in said first and second openings.
said second semiconductor package including:
(a) a semiconductor chip;
(b) a patterned lead composed of an electrical conductor and formed on said semiconductor chip in electrical contact with said semiconductor chip, said lead having a portion projecting beyond a main surface of said semiconductor chip, said projecting portion of said lead being bent along said side of said semiconductor chip;
(c) a resin film sealing said main surface of said semiconductor chip therewith;
(d) a first insulating film formed on said lead and formed in said portion with at least one opening;
(e) a second insulating film formed along a side and a bottom of said semiconductor chip;
an electrode pad formed in said opening; and
(g) a second electrode pad formed on a lower surface of said projecting portion,
said second electrode of said second semiconductor package making electrical contact with said electrode pad of said first semiconductor package, formed in said first opening, thereby said first and second semiconductor packages being electrically connected to each other.

27. A semiconductor device comprising:
(a) a plurality of semiconductor packages stacked vertically one on another; and
(b) electrically conductive bumps electrically connecting vertically adjacent semiconductor packages to each other,
each of said semiconductor packages including:
(a1) a semiconductor chip;
(a2) a patterned lead composed of an electrical conductor and formed on said semiconductor chip in electrical contact with said semiconductor chip, said lead having a portion projecting beyond a main surface of said semiconductor chip,
(a3) a resin film sealing said main surface of said semiconductor chip therewith, said electrically conductive bumps being sandwiched between a lower surface of said projecting portion of a first semiconductor package and an upper surface of said projecting portion of a second semiconductor package located just below said first semiconductor package.

28. The semiconductor device as set forth in claim 27, wherein each of said semiconductor packages further includes:
(d) a first electrode pad formed on said lead at a first end of said lead;
(e) a second electrode pad formed on said main surface of said semiconductor chip; and
(f) a first electrically conductive bump electrically connecting said first and second electrode pads to each other.

29. The semiconductor device as set forth in claim 28, wherein each of said semiconductor packages further includes a first electrically insulating layer formed at a periphery of said main surface of said semiconductor chip, said first electrically insulating layer having a thickness equal to a sum of thicknesses of said first electrode pad, said first electrically conductive bump, and said second electrode pad.

30. The semiconductor device as set forth in claim 27, wherein each of said semiconductor packages further includes a second electrically insulating layer formed on said lead.

31. The semiconductor device as set forth in claim 27, wherein said resin film is thermoplastic and adhesive.

32. The semiconductor device as set forth in claim 27, wherein each of said semiconductor packages further includes a third electrode pad(s) formed on at least one of opposite surfaces of said projecting portion of said lead.

33. The semiconductor device as set forth in claim 27, wherein each of said semiconductor packages further includes a third electrically insulating layer formed on a side of said semiconductor chip.

34. The semiconductor device as set forth in claim 32, wherein said third electrically insulating layer is formed further on a bottom of said semiconductor chip.

35. The semiconductor device as set forth in claim 29, wherein said second electrically insulating layer is formed also on said projecting portion of said lead, said second electrically insulating layer being formed with at least one opening on said projecting portion of said lead,
said semiconductor device further comprising a third electrode pad formed in said opening in electrical contact with said lead.

36. The semiconductor device as set forth in claim 29, wherein said first electrically insulating layer has a thickness of 50 micrometers of smaller.

37. The semiconductor device as set forth in claim 30, wherein said second electrically insulating layer is formed with at least one through-hole through which resin which will make said resin film enters a gap between said lead and said semiconductor chip.

38. A semiconductor device comprising a plurality of semiconductor packages stacked vertically one on another,
each of said semiconductor packages including:
(a1) a semiconductor chip; and
(a2) a patterned lead composed of an electrical conductor and formed on said semiconductor chip in electrical contact with said semiconductor chip,
said lead having a portion projecting beyond a main surface of said semiconductor chip, said portion being bent along a side of said semiconductor chip,
said portion of a first semiconductor package being in electrical contact with said portion of a second semiconductor package located just below said first semiconductor package, thereby said first and second semiconductor packages being electrically connected to each other.

39. The semiconductor device as set forth in claim 38, wherein each of said semiconductor packages further includes:
(d) a first electrode pad formed on said lead at a first end of said lead;
(e) a second electrode pad formed on said main surface of said semiconductor chip; and
(f) a first electrically conductive bump electrically connecting said first and second electrode pads to each other.

40. The semiconductor device as set forth in claim 39, wherein each of said semiconductor packages further includes a first electrically insulating layer formed at a periphery of said main surface of said semiconductor chip, said first electrically insulating layer having a thickness equal to a sum of thicknesses of said first electrode pad, said first electrically conductive bump, and said second electrode pad.

41. The semiconductor device as set forth in claim 38, wherein each of said semiconductor packages further includes a second electrically insulating layer formed on said lead.

42. The semiconductor device as set forth in claim 38, wherein said resin film is thermoplastic and adhesive.

43. The semiconductor device as set forth in claim 38, wherein each of said semiconductor packages further includes a third electrode pad(s) formed on at least one of opposite surfaces of said projecting portion of said lead.

44. The semiconductor device as set forth in claim 38, wherein each of said semiconductor packages further includes a third electrically insulating layer formed on a side of said semiconductor chip.

45. The semiconductor device as set forth in claim 43, wherein said third electrically insulating layer is formed further on a bottom of said semiconductor chip.

46. The semiconductor device as set forth in claim 40, wherein said second electrically insulating layer is formed also on said projecting portion of said lead, said second electrically insulating layer being formed with at least one opening on said projecting portion of said lead,
said semiconductor device further comprising a third electrode pad formed in said opening in electrical contact with said lead.

47. The semiconductor device as set forth in claim 40, wherein said first electrically insulating layer has a thickness of 50 micrometers of smaller.

48. The semiconductor device as set forth in claim 41, wherein said second electrically insulating layer is formed with at least one through-hole through which resin which will make said resin film enters a gap between said lead and said semiconductor chip.

49. A semiconductor device comprising:
(a) a plurality of semiconductor packages stacked vertically one on another; and
(b) a connector electrically connecting said semiconductor packages to one another,
each of said semiconductor packages including:
(a1) a semiconductor chip; and
(a2) a patterned lead composed of an electrical conductor and formed on said semiconductor chip in electrical contact with said semiconductor chip,
said lead having a portion projecting beyond a main surface of said semiconductor chip, said portion being bent along a side of said semiconductor chip,
said connector making electrical contact with said portion of each of said semiconductor packages, thereby said semiconductor packages being electrically connected to one another through said connector.

50. A method of fabricating a semiconductor device, comprising the steps of:
(a) forming a first electrode pad on a lower surface of a lead;
(b) forming a second electrode pad and a first insulating layer on a main surface of a semiconductor chip, said lead having a portion projecting beyond said main surface of said semiconductor chip;
(c) forming a first electrically conductive bump on at least one of said first and second electrode pads, said first insulating layer having a thickness equal to a sum of thicknesses of said first electrode, said second electrode and said first electrically conductive bump; (d) coupling said semiconductor chip and said lead to each other by thermal compression or re-flowing of said first electrically conductive bump;
(e) sealing said main surface of said semiconductor chip with resin; and
(f) forming a third electrode pad on at least one of upper and lower surfaces of said projecting portion.

51. The method as set forth in claim 50, further comprising the step of forming a second electrically conductive bump on a lower surface of said projection portion of said lead.

52. A method of fabricating a semiconductor device, comprising the steps of:
(a) forming a first electrically insulating layer on a wafer, on which a semiconductor device has been fabricated, around said semiconductor device;
(b) forming a first electrode pad on said wafer;
(c) forming a first electrically conductive bump on said first electrode pad;
(d) connecting said first electrode to a second electrode formed on a lead at its end by carrying out thermal compression or re-flowing of said first electrically conductive bump at a time in the entirety of said wafer;
(e) sealing said wafer and said lead with resin; and
(f) cutting said semiconductor device and said lead at a lower surface of said wafer into individual semiconductor devices.
